(19) United States
(12) Patent Application Publication
(10) Pub. No.: US 2026/0215331 A1
(43) Pub. Date: Jul. 23, 2026

(54) SEMICONDUCTOR DEVICE AND METHOD OF MANUFACTURING SEMICONDUCTOR DEVICE

(71) Applicant: FUJI ELECTRIC CO., LTD., Kawasaki-shi (JP)

(72) Inventor: Daisuke INOUE, Matsumoto-city (JP)

(73) Assignee: FUJI ELECTRIC CO., LTD., Kawasaki-shi (JP)

(21) Appl. No.: 19/568,400

(22) Filed: Mar. 16, 2026

Related U.S. Application Data
(63) Continuation of application No. PCT/JP2025/006388, filed on Feb. 25, 2025.

(30) Foreign Application Priority Data
Mar. 22, 2024 (JP) 2024-046523

(51) Int. Cl. H10W 76/12; H10W 76/47

(52) U.S. Cl. CPC H10W 76/165; H10W 76/167; H10W 76/47

(57) ABSTRACT

A semiconductor device, including: a circuit board; a case which includes a housing member with a rectangular outer shape in a plan view of the semiconductor device and houses the circuit board, the housing member including an upper surface portion having a lower surface thereof facing an upper surface of the housed circuit board with a gap therebetween, the upper surface portion including a first edge portion at an edge thereof in the plan view; a first external connection terminal that is held by the first edge portion and protrudes from the first edge portion in a direction that is perpendicular to an upper surface of the first edge portion; and an encapsulating member that encapsulates the gap between the upper surface of the circuit board and the lower surface of the upper surface portion.

### CROSS-REFERENCE TO RELATED APPLICATION(S)

This application is a continuation application of International Application PCT/JP2025/006388 filed on Feb. 25, 2025, which designated the U.S., and claims priority to Japanese Patent Application No. 2024-046523, filed on Mar. 22, 2024, the entire contents of which are incorporated herein by reference.

### BACKGROUND OF THE INVENTION

### 1. Field of the Invention

The embodiment discussed herein relates to a semiconductor device and a method of manufacturing a semiconductor device.

### 2. Background of the Related Art

A proposed semiconductor device includes a case, which is equipped with a semiconductor circuit, and a component, which is attachable to the case and equipped with a signal terminal and wiring, the wiring including a spring portion provided between an upper part of a lead portion and a contact portion (see, for example, Japanese Laid-open Patent Publication No. 2023-135187).

Another proposed semiconductor device includes a plate-shaped first terminal, which is provided to face a first main surface of an insulating sheet and includes a protruding portion that protrudes to the outside of the first main surface, and a plate-shaped second terminal, which is provided corresponding to a second main surface of the insulating sheet and includes a protruding portion that protrudes to the outside of the second main surface (see, for example, Japanese Laid-open Patent Publication No. 2023-88055).

A proposed bonding structure includes a substrate, which has a conductor layer as one surface layer, and a power supply terminal including a first portion that overlaps the conductor layer when viewed in a thickness direction and a second portion that extends from the first portion in a direction that is perpendicular to the thickness direction (see, for example, see Japanese Laid-open Patent Publication No. 2022-189515).

Another proposed semiconductor device includes a plurality of pins that are press-fitted into a printed circuit board, a resin block in which a plurality of through holes, into which the pins are press-fitted, are formed, and a resin case that covers at least part of the printed circuit board and the resin block (see, for example, Japanese Laid-open Patent Publication No. 2018-107395).

In yet another proposed semiconductor device, a plurality of signal pin terminals and guide pins are arranged in a row and extend out of a resin case in which a main circuit power element and a control circuit element are incorporated (see, for example, Japanese Registered Utility Model No. 3025083).

Yet another proposed semiconductor device includes a plurality of semiconductor modules that each have a semiconductor chip mounted on an insulating circuit board, are provided inside a case, and have an external connection terminal that is connected to the semiconductor chip or the insulating circuit board and protrudes from the case (see, for example, see Japanese Laid-open Patent Publication No. 2014-236150).

Yet another proposed semiconductor device includes a semiconductor element, a mounting portion with an upper surface on which the semiconductor element is mounted, and a plurality of terminal portions that are provided above the mounting portion, are arranged in parallel with gaps in between, and each have a bent portion at one end (see, for example, International Publication Pamphlet No. WO 2020/148879).

### SUMMARY OF THE INVENTION

According to an aspect, there is provided a semiconductor device, including: a circuit board; a case which includes a housing member with a rectangular outer shape in a plan view of the semiconductor device and houses the circuit board, the housing member including an upper surface portion having a lower surface thereof facing an upper surface of the housed circuit board with a gap therebetween, the upper surface portion including a first edge portion at an edge thereof in the plan view; a first external connection terminal that is held by the first edge portion and protrudes from the first edge portion in a direction that is perpendicular to an upper surface of the first edge portion; and an encapsulating member that encapsulates the gap between the upper surface of the circuit board and the lower surface of the upper surface portion.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view depicting the appearance of a semiconductor device;

FIG. 2 is a side view depicting the appearance of the semiconductor device;

FIG. 3 is a plan view of the semiconductor device in a state where an encapsulating member and a lid member have been removed;

FIG. 4 is a side view of the semiconductor device in a state where the encapsulating member has been removed;

FIG. 5 is a plan view of the wiring board;

FIG. 6 is a plan view of a circuit board and external connection terminals;

FIG. 7 is an enlarged cross-sectional view of part of the semiconductor device;

FIG. 8 depicts an example circuit configuration of a three-level inverter;

FIG. 9 is a flowchart depicting a manufacturing process of a semiconductor device;

FIG. 10 depicts a process of integrally molding the case and the external connection terminals;

FIG. 11 depicts a step of injecting the encapsulating member from gate ports; and

FIG. 12 is a plan view depicting a modification of the semiconductor device.

### DETAILED DESCRIPTION OF THE INVENTION

An embodiment will now be described with reference to the drawings. In the following description, an X axis and a Y axis are defined on a horizontal plane, a Z axis is defined in a direction that is perpendicular to the horizontal plane, a +Z direction is defined as upward, and a −Z direction is defined as downward. The expressions “upper surface”, “up”, “front surface”, “lower surface”, “down”, “rear surface”, and “side surface” are merely convenient expressions for specifying relative positional relationships, and do not limit the technical scope of the present disclosure. As examples, the expressions “up” and “down” do not necessarily mean the vertical direction with respect to the ground. That is, the “up” and “down” directions are not limited to the direction of gravity.

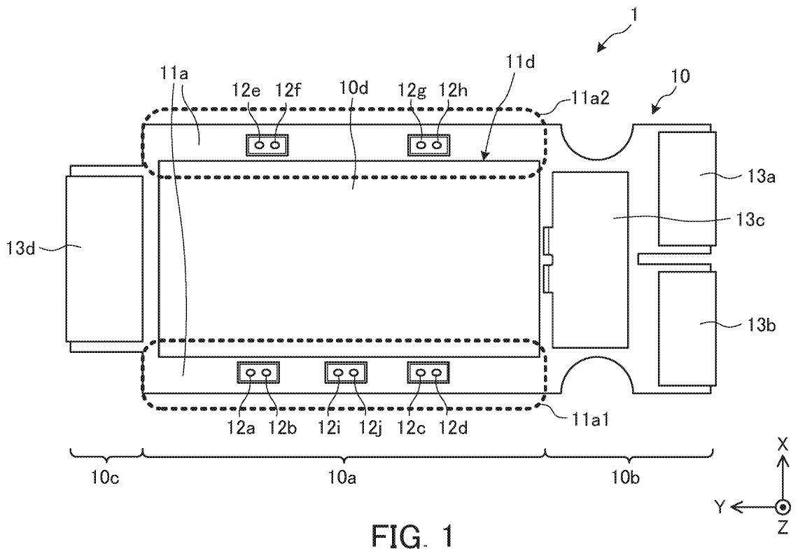

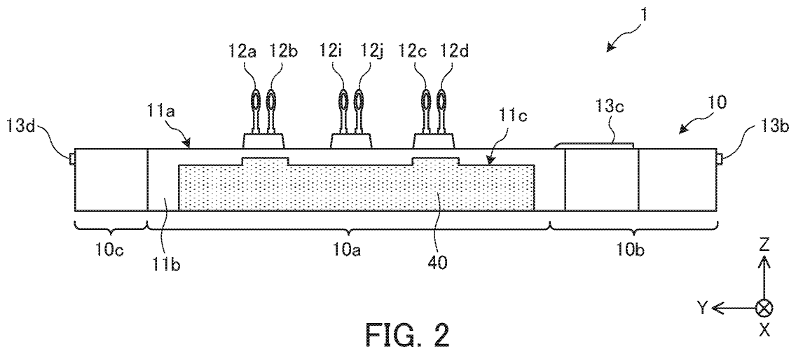

First, the appearance of a semiconductor device according to an embodiment will be described with reference to FIGS. 1 and 2. FIG. 1 is a plan view depicting the appearance of the semiconductor device. FIG. 2 is a side view depicting the appearance of the semiconductor device. Note that FIG. 2 is a side view of the semiconductor device 1 in FIG. 1 when viewed in the +X direction.

The semiconductor device 1 is a device in which a circuit board on which semiconductor chips are mounted, external connection terminals, and the like are packaged as a module. The semiconductor device 1 is attached to a front surface (that is, the surface on the +Z direction side) of a cooling module, not illustrated. As examples, this cooling module may be a heat dissipating base including heat dissipating fins or a cooling device inside which a coolant circulates.

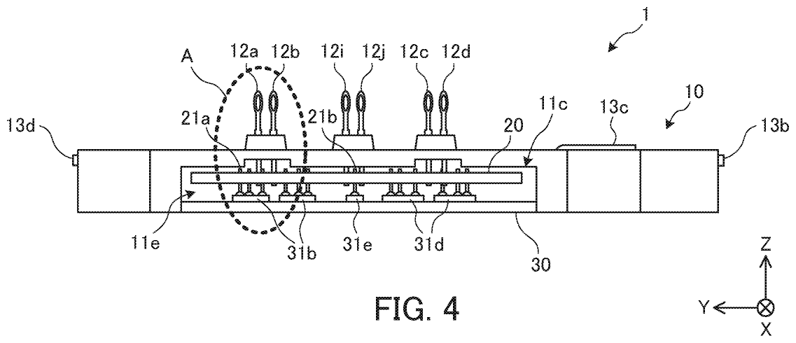

The semiconductor device 1 includes a case 10 that houses a wiring board 20 and a circuit board 30, which will be described later with reference to FIG. 4. The case 10 includes a housing member 10a, terminal holding members 10b and 10c, and a lid member 10d. The terminal holding member 10b is integrally connected to the −Y direction side of the housing member 10a, and the terminal holding member 10c is integrally connected to the +Y direction side of the housing member 10a. The lid member 10d is provided in a second opening 11d, which will be described later, provided in an upper surface of the housing member 10a.

As one example, the housing member 10a is box-shaped and includes an upper surface portion 11a that constructs an upper surface that is parallel to a horizontal plane (an X-Y plane), side walls that are parallel to a Y-Z plane, and side walls that are parallel to an X-Y plane. The side walls that are parallel to the Y-Z plane are formed below (that is, on −Z direction side of) edges on the +X direction and −X direction sides of the upper surface portion 11a. FIG. 2 depicts the side wall 11b on the −X direction side, but the reference numeral of the side wall on the +X direction side is omitted. The side walls that are parallel to the X-Y plane (whose reference numerals are also omitted) are formed below the edges on the +Y direction and the −Y direction sides of the upper surface portion 11a.

Note that the upper surface portion 11a and the side walls on the +X direction side and the −X direction side are formed as flat plates and may be integrally connected. The side wall on the +Y direction side may be integrated with an end surface on the −Y direction side of the terminal holding member 10c, and the side wall on the −Y direction side may be integrated with an end surface on the +Y direction side of the terminal holding member 10b.

The housing member 10a is also not limited to being box-shaped, and may include the upper surface portion 11a and side walls that are parallel to the X-Y plane and are formed below the edges on the +Y direction side and the −Y direction side of the upper surface portion 11a.

The upper surface portion 11a has a rectangular outer shape in plan view. The second opening 11d is formed in a central portion of the upper surface portion 11a in plan view. In the present embodiment, the second opening 11d has a rectangular outer shape in plan view, and the upper surface portion 11a (that is, the housing member 10a) is shaped in plan view as a frame that defines the second opening 11d. This second opening 11d is covered by the lid member 10d.

The housing member 10a includes a housing region 11e (see FIG. 4) which is surrounded by a lower surface of the upper surface portion 11a, the side walls on the +X direction and the −X direction sides, and the side walls on the +Y direction and the −Y direction sides. The wiring board 20 and the circuit board 30 are housed inside this housing region 11e. The upper surface portion 11a forms an upper exterior of the wiring board 20 and the circuit board 30 housed in the housing region 11e.

On the other hand, openings for injecting an encapsulating member 40 are provided on the +X direction side and the −X direction side of the housing region 11e. In the present embodiment, as one example, side walls are also provided on the +X direction side and the −X direction side of the housing region 11e, and an opening is provided in a part of each of these side walls. As one example, in FIG. 2, the side wall 11b provided on the −X direction side edge of the upper surface portion 11a is depicted. A first opening 11c that is open to below (that is, toward the −Z direction side) is formed in the side wall 11b. The first opening 11c is formed between a side wall (the terminal holding member 10c) on the +Y direction side of the housing member 10a and a side wall (the terminal holding member 10b) on the −Y direction side. The inside of the housing region 11e is encapsulated by the encapsulating member 40, and the first opening 11c is covered from the inside by the encapsulating member 40. On the upper side of the housing region 11e, the upper surface portion 11a and the lower surface of the lid member 10d are covered from the inside by the encapsulating member 40.

The upper surface portion 11a includes a first edge portion 11a1 and a second edge portion 11a2 that extend along the Y-axis on −X direction and the +X direction sides, respectively, of the second opening 11d. First external connection terminals 12a to 12d, 12i, and 12j are provided on the first edge portion 11a1 on the −X direction side of the upper surface portion 11a. First external connection terminals 12e to 12h are provided on the second edge portion 11a2 on the +X direction side of the upper surface portion 11a. The first external connection terminals 12a to 12j are columnar in shape and extend in substantially the vertical direction. This columnar shape may be prismatic or cylindrical. End portions of the first external connection terminals 12a to 12j that are exposed on the upper surface side (the +Z direction side) of the first edge portion 11a1 and the second edge portion 11a2 may be press-fitting pins.

The first external connection terminals 12a to 12d, 12i, and 12j are held by the first edge portion 11a1 in a state where the first external connection terminals 12a to 12d, 12i, and 12j pass through the first edge portion 11a1 in the vertical direction (±Z direction). The first external connection terminals 12e to 12h are held by the second edge portion 11a2 in a state where the first external connection terminals 12e to 12h pass through the second edge portion 11a2 in the vertical direction (±Z direction). Upper end portions of the first external connection terminals 12a to 12j that protrude from the upper surface of the upper surface portion 11a serve as connection terminal portions to be connected to an external circuit. On the other hand, lower end portions of the first external connection terminals 12a to 12j that protrude from the lower surface of the upper surface portion 11a are inserted as described later into wiring holes provided in the wiring board 20 and are electrically connected to a wiring layer formed on the wiring board 20.

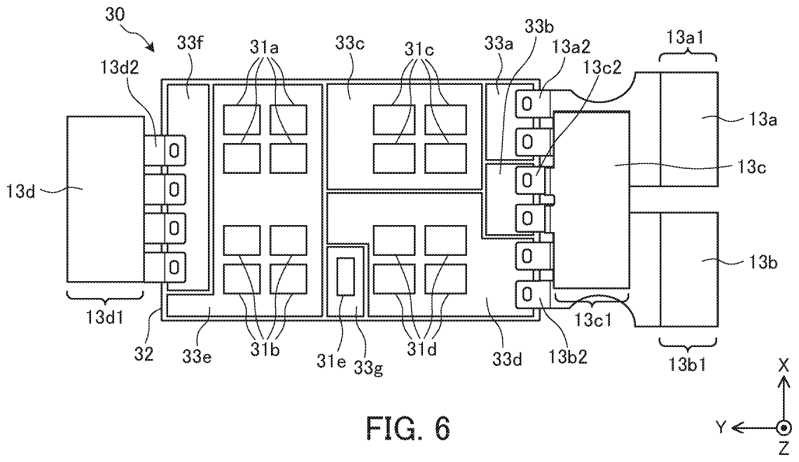

The terminal holding member 10b is provided with second external connection terminals 13a to 13c. Flat plate portions 13a1 to 13c1 (see FIG. 6) are formed at end portions (outer end portions) on the −Y direction sides of the second external connection terminals 13a to 13c, respectively. The second external connection terminals 13a to 13c are held by the terminal holding member 10b in a state where upper surfaces of the flat plate portions 13a1 to 13c1 are exposed on an upper surface of the terminal holding member 10b. The flat plate portions 13a1 to 13c1 exposed on the upper surface of the terminal holding member 10b serve as connection terminal portions to be connected to an external circuit. On the other hand, the end portions (inner end portions) on the +Y direction sides of the second external connection terminals 13a to 13c are connected as described later to a circuit pattern on an upper surface of the circuit board 30 inside the housing member 10a.

The terminal holding member 10c is provided with a second external connection terminal 13d. A flat plate portion 13d1 (see FIG. 6) is formed at an end portion (outer

end portion) on the +Y direction side of the second external connection terminal 13d. The second external connection terminal 13d is held by the terminal holding member 10c in a state where an upper surface of the flat plate portion 13d1 is exposed at an upper surface on the terminal holding member 10c. The flat plate portion 13d1 exposed on the upper surface of the terminal holding member 10c serves as a connection terminal portion to be connected to an external circuit. On the other hand, an end portion (inner end portion) on the −Y direction side of the second external connection terminal 13d is connected as described later to a circuit pattern on the upper surface of the circuit board 30 inside the housing member 10a.

In the present embodiment, a three-level inverter circuit is constructed by the wiring board 20, the circuit board 30, and semiconductor chips, described later, which are housed inside the case 10. The second external connection terminals 13a to 13d correspond to an N terminal, a P terminal, a neutral terminal, and an output terminal of the three-level inverter circuit, respectively. The first external connection terminals 12a to 12h correspond to control terminals for controlling switching operations of transistors included in the three-level inverter circuit. The first external connection terminals 12i and 12j correspond to output terminals that output various sensing signals.

Note that the case 10 including the housing member 10a and the terminal holding members 10b and 10c includes parts of the first external connection terminals 12a to 12j and the second external connection terminals 13a to 13d, and is integrally molded by injection molding using thermoplastic resin. The lid member 10d is separately formed by injection molding using thermoplastic resin. As examples, the thermoplastic resin is polyphenylene sulfide resin, polybutylene terephthalate resin, polybutylene succinate resin, polyamide resin, acrylonitrile butadiene styrene resin, or a liquid crystal polymer. The first external connection terminals 12a to 12j and the second external connection terminals 13a to 13d are formed of a metal with superior electrical conductivity. Example metals include copper, aluminum, or an alloy containing at least one of such metals as a main component.

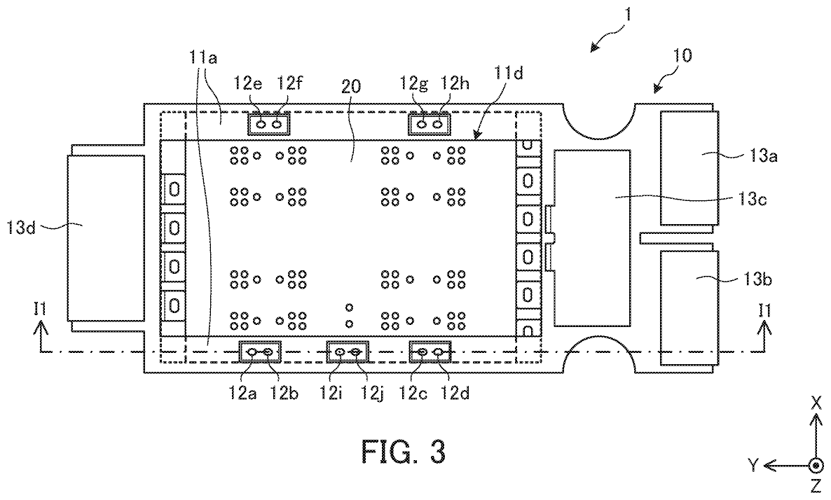

FIG. 3 is a plan view of the semiconductor device in a state where the encapsulating member and the lid member have been removed. FIG. 4 is a side view of the semiconductor device in a state where the encapsulating member has been removed.

The wiring board 20 and the circuit board 30 are housed inside the housing member 10a (on the lower surface side of the upper surface portion 11a). The wiring board 20 and the circuit board 30 are both rectangular in shape in plan view. The wiring board 20 is disposed at a gap from the lower surface of the upper surface portion 11a in a state where the upper surface of the wiring board 20 faces the lower surface of the upper surface portion 11a. A plurality of wiring holes (described later) pass through the wiring board 20 and lower ends of the first external connection terminals 12a to 12j are press-fitted into corresponding wiring holes to fix the wiring board 20 to the upper surface portion 11a. The first external connection terminals 12a to 12j are electrically connected to the wiring layer included in the wiring board 20. The circuit board 30 is disposed at a gap from a lower surface of the wiring board 20 in a state where the upper surface of the circuit board 30 faces the lower surface of the wiring board 20.

A plurality of semiconductor chips are mounted on the upper surface of the circuit board 30. FIG. 4 depicts semiconductor chips 31b, 31d, and 31e out of such semiconductor chips. A plurality of wiring pins that are columnar and extend in the vertical direction are inserted through the wiring board 20. An upper end of each wiring pin is electrically connected to the wiring layer included in the wiring board 20, and a lower end of each wiring pin is electrically connected via solder to an output electrode and a control electrode on an upper surface of a corresponding semiconductor chip. As one example, in FIG. 4, wiring pins 21a and 21b are provided on the wiring board 20, and the lower ends of the wiring pins 21a and 21b and the upper surfaces of the semiconductor chips 31b and 31e are electrically connected to each other via solder. Accordingly, the first external connection terminals 12a to 12j are electrically connected via the wiring board 20 and the wiring pins to the output electrodes and the control electrodes of the semiconductor chips.

In addition, in a state where the wiring board 20 and the circuit board 30 have been disposed on the upper surface portion 11a as described above, at least a region between the lower surface of the upper surface portion 11a and the upper surface of the circuit board 30 is filled with the encapsulating member 40, thereby encapsulating the wiring board 20 and the semiconductor chips with the encapsulating member 40.

In the present embodiment, the outer edge of the circuit board 30 and the side walls below the upper surface portion 11a do not contact the terminal holding members 10b and 10c in plan view. This means that the encapsulating member 40 is filled so as to also cover side surfaces of the circuit board 30, with a rear surface of the circuit board 30 and parts of the encapsulating member 40 that cover the side surfaces of the circuit board 30 exposed from a lower side (that is, the −Z direction side) of the housing region 11e. The rear surface of the circuit board 30 may be flush with the rear surfaces of the housing member 10a of the case 10 and the terminal holding members 10b and 10c.

A thermosetting resin is used as the encapsulating material of the encapsulating member 40. As one example, the thermosetting resin is epoxy resin. By using such a resin, the semiconductor device 1 that is highly rigid is manufactured by performing transfer molding on the case 10 in which the wiring board 20, the circuit board 30, and the semiconductor chips have been housed. High rigidity for the semiconductor device 1 is achieved especially in the vertical direction (the Z-axis direction), so that even when an external force is applied in the vertical direction, it is possible to

maintain predetermined gaps between the upper surface portion 11a and the wiring board 20 and between the wiring board 20 and the circuit board 30.

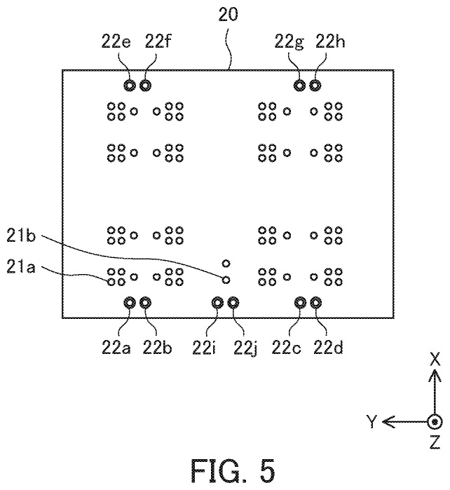

FIG. 5 is a plan view of the wiring board. As one example, the wiring board 20 is a printed circuit board (PCB) with a multilayer structure. As examples of the wiring board 20, a wiring layer may be formed on at least one of the upper surface and the lower surface of an insulating layer, and one or more wiring layers may also be formed inside the insulating layer.

The insulating layer is formed of an insulating resin, for example. As examples, the insulating resin is a paper phenol substrate, a paper epoxy substrate, a glass composite substrate, or a glass epoxy substrate. Each wiring layer is formed of a metal with superior electrical conductivity. Example metals include copper, aluminum, or an alloy containing at least one of such metals as a main component.

The wiring board 20 is provided with a plurality of wiring holes (through holes) that pass through the wiring board 20, with wiring pins being inserted into these wiring holes. The wiring pins are formed of a metal with superior electrical conductivity. Each wiring hole is connected to a circuit pattern on a wiring layer formed on the wiring board 20, so that each wiring pin becomes electrically connected to the circuit pattern connected to the wiring hole into which the wiring pin is inserted. Such wiring pins protrude on at least the lower surface sides of the corresponding wiring holes. The wiring pins may additionally protrude on the upper surface sides of the corresponding wiring holes by an amount where the wiring pins do not contact with the lower surface of the upper surface portion 11a.

Note that the wiring pins 21a and 21b are depicted in FIG. 5 as examples of such wiring pins. As depicted in FIG. 4, the lower ends of the wiring pins 21a and 21b are electrically connected via solder to the output electrodes and the control electrodes on the upper surfaces of the semiconductor chips 31b and 31e mounted on the circuit board 30.

Wiring holes (through holes) 22a to 22j pass through the wiring board 20. The wiring holes 22a to 22d, 22i, and 22j are arranged along the −X direction side edge portion of the wiring board 20. This edge portion corresponds to a region that faces the lower surface of the first edge portion 11a1 of the upper surface portion 11a when the wiring board 20 is attached to the upper surface portion 11a. The lower ends of the first external connection terminals 12a to 12d, 12i, and 12j are inserted into the wiring holes 22a to 22d, 22i, and 22j, respectively. The wiring holes 22e to 22h are arranged along the +X direction side edge portion of the wiring board 20. This edge portion is a region that faces the lower surface of the second edge portion 11a2 of the upper surface portion 11a when the wiring board 20 is attached to the upper surface portion 11a. The lower ends of the first external connection terminals 12e to 12h are inserted into the wiring holes 22e to 22h, respectively.

The wiring holes 22a to 22j are also connected to a circuit pattern of a wiring layer formed on the wiring board 20. By inserting the lower ends of the first external connection terminals 12a to 12j into the wiring holes 22a to 22j, the first external connection terminals 12a to 12j are electrically connected to the circuit patterns connected to the wiring holes 22a to 22j into which such first external connection terminals 12a to 12j are inserted.

In addition, via holes for electrically connecting wiring layers may pass through the wiring board 20.

FIG. 6 is a plan view of a circuit board and external connection terminals. As described earlier, the second external connection terminals 13a to 13d are integrally formed with the case 10. FIG. 6 depicts the second external connection terminals 13a to 13d and the circuit board 30 in a state where the case 10 has been removed.

The circuit board 30 includes an insulating plate 32 that forms a bottom surface, circuit patterns 33a to 33g formed on an upper surface (the surface on the +Z direction side) of the insulating plate 32, and a metal plate (not illustrated) formed on a lower surface (the surface on the −Z direction side) of the insulating plate 32. Semiconductor chips 31a to 31e are mounted on the circuit board 30.

The insulating plate 32 is made of resin, for example. Such resin may be a material that has low thermal resistance and is highly electrically insulating. Example resins include thermosetting resin and thermoplastic resin. Examples of such thermosetting resin include at least one of epoxy resin, cyanate resin, polyimide resin, benzoxazine resin, unsaturated polyester resin, phenol resin, melamine resin, silicone resin, and maleimide resin. Examples of such thermoplastic resin include at least one of acrylic resin and polyamide resin. These resins may also contain filler. The filler is made of at least one of an oxide and a nitride. Example oxides include silicon oxide and aluminum oxide. Example nitrides include silicon nitride, aluminum nitride, and boron nitride. Hexagonal boron nitride may also be used as the filler.

The insulating plate 32 may be a ceramic substrate instead of resin. Such ceramic substrate is made of a ceramic with favorable thermal conductivity. As one example, the ceramic is made of a material containing aluminum oxide, aluminum nitride, or silicon nitride as a main component. As examples, a direct copper bonding (DCB) substrate or an active metal brazed (AMB) substrate may be used as the circuit board 30 including the insulating plate 32 with the configuration described above.

Note that in the present embodiment, the insulating plate 32 is made of resin, and the difference between the linear expansion coefficient of the insulating plate 32 and the linear expansion coefficients of the metal plate and the circuit patterns 33a to 33g is small.

The circuit patterns 33a to 33f and the metal plate are formed of a metal with superior electrical conductivity. Example metals include copper, aluminum, or an alloy containing at least one of these metals as a main component.

The semiconductor chips 31a to 31d may be power metal-oxide-semiconductor field-effect transistors (MOSFETs) with silicon carbide as a main component. In a power MOSFET, the body diode may function as a freewheeling diode (FWD). As one example, each of the semiconductor chips 31a to 31d includes an input electrode (drain electrode) as a main electrode on a rear surface, and an output electrode (source electrode) and a control electrode (gate electrode) as main electrodes on a front surface.

Alternatively, the semiconductor chips 31a to 31d may include switching elements that have silicon as a main component. As one example, the switching elements may be reverse-conducting insulated gate bipolar transistors (RC-IGBT). An RC-IGBT is a semiconductor element in which an IGBT and an FWD are arranged in anti-parallel in a single chip. As one example, each of the semiconductor chips 31a to 31d includes an input electrode (collector electrode) as a main electrode on a rear surface, and an output electrode (emitter electrode) and a control electrode (gate electrode) as main electrodes on a front surface.

In addition, the semiconductor chips 31a to 31d may be semiconductor chips each including a pair of a switching element and a diode element that are formed of silicon as a main component. As examples, the switching element is a power MOSFET or an IGBT. As examples, a semiconductor chip including a switching element includes an input electrode (a drain electrode for a power MOSFET or a collector electrode for an IGBT) as a main electrode on a rear surface, and a gate electrode as a control electrode and an output electrode (a source electrode for a power MOSFET or an emitter electrode for an IGBT) as a main electrode on a front surface. As examples of diode elements, a Schottky barrier diode (SBD) or a P-intrinsic-N (PiN) diode is used as an FWD. A semiconductor chip including a diode element includes, for example, an output electrode (cathode electrode) as a main electrode on a rear surface and an input electrode (anode electrode) as a main electrode on a front surface.

In the present embodiment, the semiconductor chips 31a to 31d are power MOSFETs that have silicon carbide as a main component.

As one example, four semiconductor chips 31c are mounted on the upper surface of the circuit pattern 33c. Although not depicted, the input electrodes on the lower surfaces of the semiconductor chips 31c are electrically connected via solder to the upper surface of the circuit pattern 33c. As one example, four semiconductor chips 31d are mounted on the upper surface of a circuit pattern 33d. Although not depicted, the input electrodes on the lower surfaces of the semiconductor chips 31d are electrically connected via solder to the upper surface of the circuit pattern 33d. As one example, four semiconductor chips 31a and four semiconductor chips 31b are mounted on the upper surface of a circuit pattern 33e. Although not depicted, the input electrodes on the lower surfaces of the semiconductor chips 31a and 31b are electrically connected via solder to the upper surface of the circuit pattern 33e.

The semiconductor chip 31e is mounted on the upper surface of the circuit pattern 33g. The semiconductor chip 31e includes a semiconductor element that performs various sensing operations. As one example, the semiconductor chip 31e includes a diode element that detects temperature. Although not depicted, an electrode provided on the lower surface of the semiconductor chip 31e is electrically connected via solder to the upper surface of the circuit pattern 33g.

The circuit pattern 33a is electrically connected to the second external connection terminal 13a. In more detail, the flat plate portion 13a1 is formed at a −Y direction side end portion of the second external connection terminal 13a. In addition, at a +Y direction side end portion of the flat plate portion 13a1 of the second external connection terminal 13a, connecting portions 13a2 in the form of flat plates in the horizontal direction are formed via an intermediate portion (not illustrated) that extends in the downward direction (the −Z direction). Lower surfaces of the connecting portions 13a2 are bonded to the upper surface of the circuit pattern 33a.

The circuit pattern 33b is electrically connected to the second external connection terminal 13c. In more detail, a flat plate portion 13c1 is formed at a −Y direction side end portion of the second external connection terminal 13c. In addition, at a +Y direction side end portion of the flat plate portion 13c1 of the second external connection terminal 13c, connecting portions 13c2 in the form of flat plates in the horizontal direction are formed via intermediate portions (not depicted) that extend in the downward direction (the −Z direction). Lower surfaces of the connecting portions 13c2 are bonded to the upper surface of the circuit pattern 33b.

The circuit pattern 33d is electrically connected to the second external connection terminal 13b. In more detail, a flat plate portion 13b1 is formed at a −Y direction side end portion of the second external connection terminal 13b.

In addition, at a +Y direction side end portion of the flat plate portion 13b1 of the second external connection terminal 13b, connection portions 13b2 in the form of flat plates in the horizontal direction are formed via intermediate portions (not depicted) that extend in the downward direction (−Z direction). Lower surfaces of the connection portions 13b2 are bonded to the upper surface of the circuit pattern 33d.

The circuit pattern 33f is electrically connected to the second external connection terminal 13d. In more detail, a flat plate portion 13d1 is formed at a +Y direction side end portion of the second external connection terminal 13d. In addition, at a −Y direction side end portion of the flat plate portion 13d1 of the second external connection terminal 13d, connection portions 13d2 in the form of flat plates in the horizontal direction are formed via intermediate portions (not depicted) that extend in the downward direction (the −Z direction). Lower surfaces of the connection portions 13d2 are bonded to the upper surface of the circuit pattern 33f.

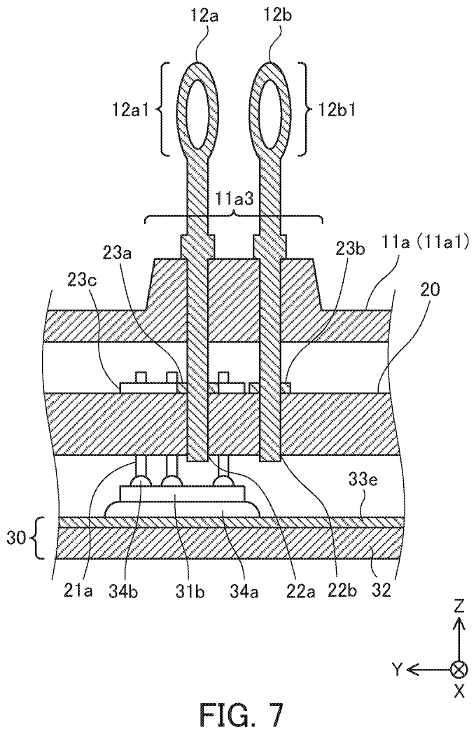

FIG. 7 is an enlarged cross-sectional view of part of the semiconductor device. FIG. 7 is an enlarged cross-sectional view of the region A in FIG. 4 taken along the line I1-I1 in FIG. 3.

In the region A, the first external connection terminals 12a and 12b are held by the first edge portion 11a1 in a state where the first external connection terminals 12a and 12b pass through the first edge portion 11a1 of the upper surface portion 11a in the vertical direction (the Z-axis direction). The lower ends of the first external connection terminals 12a and 12b are inserted into the wiring holes 22a and 22b, respectively, provided in the wiring board 20. As one example, circuit patterns 23a and 23b are formed on the upper surface of the wiring board 20 at positions surrounding the wiring holes 22a and 22b, respectively. By inserting the lower ends of the first external connection terminals 12a and 12b into the wiring holes 22a and 22b, the first external connection terminals 12a and 12b are electrically connected to the circuit patterns 23a and 23b, respectively. By press-fitting the lower ends of the first external connection terminals 12a and 12b into the wiring holes 22a and 22b, the position of the wiring board 20 with respect to the first edge portion 11a1 of the upper surface portion 11a is fixed.

The wiring pin 21a is inserted through the wiring board 20 and as one example, the wiring pin 21a is electrically connected to a circuit pattern 23c formed on the upper surface of the wiring board 20. On the other hand, the circuit pattern 33e is formed on the upper surface of the insulating plate 32 of the circuit board 30, and the semiconductor chip 31b is mounted via solder 34a on the upper surface of the circuit pattern 33e. The lower ends of the wiring pins 21a are bonded via solder 34b to the upper surface of the semiconductor chip 31b.

As described above, a gap is provided between the lower surface of the wiring board 20 and the upper surface of the circuit board 30 for bonding the wiring pin and the semiconductor chip via solder. As described earlier, the housing region 11e between the lower surface of the upper surface portion 11a and the upper surface of the circuit board 30 is filled with the encapsulating member 40 so as to include the wiring board 20. When the introduced encapsulating member 40 is cured, the circuit board 30 is fixed to the case 10 in a state where a predetermined gap is maintained between the lower surface of the wiring board 20 and the upper surface of the circuit board 30.

In the present embodiment, the first external connection terminals 12a and 12b are press-fitting pins, and +Z direction side end portions (outer end portions) 12a1 and 12b1 of the first external connection terminals 12a and 12b are elastically deformable. The other first external connection terminals 12c to 12j are also press-fitting pins of the same configuration. Each press-fitting pin is press-fitted into a receiving part. This means that at the time of press-fitting, a load is applied in the longitudinal direction of the first external connection terminals 12a to 12j, that is, in a direction (the Z-axis direction) that is perpendicular to the upper surface of the case 10. As described above, the −Z direction side end portions (inner end portions) of the first external connection terminals 12a and 12b are press-fitted into the wiring holes 22a to 22j of the wiring board 20. During press-fitting, a load acts in the same way in a direction perpendicular to the upper surface of the case 10.

In the present embodiment, the first external connection terminals 12a to 12j are held by the case 10 and the semiconductor device 1 including this case 10 is manufactured by transfer molding. By using a structure where the first external connection terminals 12a to 12j are held by the case 10, it is possible to increase the strength of the first external connection terminals 12a to 12j with respect to loads in the vertical direction.

Typically, for a transfer mold-type semiconductor module, external connection terminals to which tie-bar terminals are connected are often molded so as to be enclosed by resin. When a semiconductor module with such a structure is provided with external connection terminals that are oriented in a direction perpendicular to the main surface of the semiconductor module, as one example, carrier portions of the tie-bar terminals are cut after transfer molding and then the external connection terminals that protrude from the semiconductor module in a direction (the horizontal direction) that is parallel to the main surface are bent in the vertical direction. In this case, the rigidity of the external connection terminals in the vertical direction is low, making it difficult to provide external connection terminals to which a load is applied in the vertical direction as those described above.

In contrast, although the semiconductor device 1 according to the present embodiment is manufactured by transfer molding, the semiconductor device 1 uses the case 10 that holds the first external connection terminals 12a to 12j so as to extend vertically upward. This makes it possible to realize the semiconductor device 1 including the first external connection terminals 12a to 12j with high strength with respect to a load in the vertical direction.

The case 10 and the first external connection terminals 12a to 12j are integrally formed by injection molding. When doing so, by preparing a die for molding each shape of the case 10, it is possible to easily mold cases 10 of various shapes. This means that there is a high degree of freedom in designing the mounting position and the number of external connection terminals that extend in the vertical direction.

In addition, the degree of freedom in designing the shape of the case 10 is high. For the example in the present embodiment, as depicted in FIG. 7, in the region of the first edge portion 11a1 of the upper surface portion 11a, the attachment region 11a3 through which the first external connection terminals 12a and 12b pass is formed to be thicker in the vertical direction than other regions. This increases the attachment strength of the first external connection terminals 12a and 12b. In this way, the degree of freedom in designing the thickness of the case 10, such as the upper surface portion 11a, is high. An opening for injecting the encapsulating member 40 is provided in a side wall (for example, the side wall 11b) on an X-axis direction side of the housing member 10a of the case. The degree of freedom in designing the position, size, and shape of such opening is also high.

Also, by performing molding as described above, it is possible to manufacture the case 10 accurately as designed. For example, the first external connection terminals 12a to 12j protrude on the upper surface side (+Z direction side) of the case 10. On the other hand, during transfer molding, a die (upper die) is brought into close contact with the upper surface side of the case 10. For this reason, the first external connection terminals 12a to 12j that protrude need to be accurately aligned and inserted into the cavity of the die, and high accuracy is needed for the horizontal positions of the first external connection terminals 12a to 12j of the case 10. Since the case 10 and the first external connection terminals 12a to 12j are integrally molded by injection molding, it is possible to improve the mounting position accuracy of the first external connection terminals 12a to 12j in the case 10 in the horizontal direction.

As described above, the semiconductor device 1 is manufactured by transfer molding using the case 10 which holds the first external connection terminals 12a to 12j, which makes it possible to manufacture semiconductor devices 1 of various specifications with high accuracy.

Note that as the first external connection terminals 12a to 12j, as another example solder pins may be used in place of the press-fitting pins.

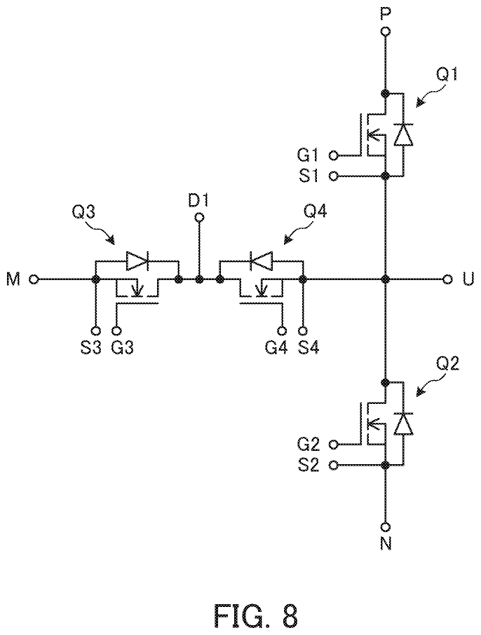

FIG. 8 depicts an example circuit configuration of a three-level inverter. As one example, the semiconductor device 1 includes a three-level inverter as depicted in FIG. 8. The three-level inverter is a T-type neutral point clamped (NPC) inverter circuit, and includes four transistors Q1 to Q4. The transistor Q1 corresponds to the semiconductor chip 31d, and the transistor Q2 corresponds to the semiconductor chip 31c. The transistor Q3 corresponds to the semiconductor chip 31b, and the transistor Q4 corresponds to the semiconductor chip 31a.

The drain electrode of the transistor Q1 is connected via the circuit board 30 to a P terminal, which is an input terminal on the positive electrode side. The P terminal corresponds to the second external connection terminal 13b. The source electrode of the transistor Q2 is connected via the wiring board 20 and the circuit board 30 to an N terminal, which is an input terminal on the negative electrode side. The N terminal corresponds to the second external connection terminal 13a.

A drain electrode of the transistor Q3 and a drain electrode of the transistor Q4 are connected to each other via the circuit board 30, and a source electrode of the transistor Q3 is connected via the wiring board 20 and the circuit board 30 to an M terminal (neutral terminal) which is an input terminal of an intermediate potential. The M terminal corresponds to the second external connection terminal 13c.

The source electrode of the transistor Q1, the drain electrode of the transistor Q2, and the source electrode of the transistor Q4 are connected to each other via the circuit board 30 and the wiring board 20, and a junction between such electrodes is connected via the wiring board 20 and the circuit board 30 to a U terminal which is an output terminal. The U terminal corresponds to the second external connection terminal 13d.

The gate electrodes of the transistors Q1 to Q4 are respectively connected via the wiring board 20 to gate terminals (control terminals) G1 to G4, which are input terminals for control signals used for switching operations. The gate terminals G1 to G4 correspond to the first external connection terminals 12c, 12g, 12b, and 12f, respectively. Note that the source electrodes of the transistors Q1 to Q4 are connected via the wiring board 20 respectively to the auxiliary source terminals S1 to S4, which are output terminals. The auxiliary source terminals S1 to S4 correspond to the first external connection terminals 12d, 12h, 12a, and 12e, respectively.

In this three-level inverter, when the control signals to the gate terminals G1 and G2 are on and the control signals to the gate terminals G3 and G4 are off, the output voltage from the U terminal is E/2. When the control terminals connected to the gate terminals G2 and G3 are on and the control terminals connected to the gate terminals G1 and G4 are off, the output voltage from the U terminal is 0. When the control signals to the gate terminals G3 and G4 are on and the control signals to the gate terminals G1 and G2 are off, the output voltage from the U terminal is −E/2.

As described above, the transistors Q1 to Q4 included in the three-level inverter correspond to the semiconductor chips 31a to 31d, respectively. As depicted in FIG. 6, the semiconductor device 1 according to the present embodiment includes four each of the semiconductor chips 31a to 31d. For this reason, the semiconductor device 1 includes four sets of three-level inverters each including one each of the semiconductor chips 31a to 31d, with these three-level inverters being connected in parallel.

Although not depicted, the semiconductor device 1 which includes parallel three-level inverters as described above are used in a combination of three. One semiconductor device 1 generates a U-phase output voltage, another semiconductor device 1 generates a V-phase output voltage, and another semiconductor device 1 generates a W-phase output voltage.

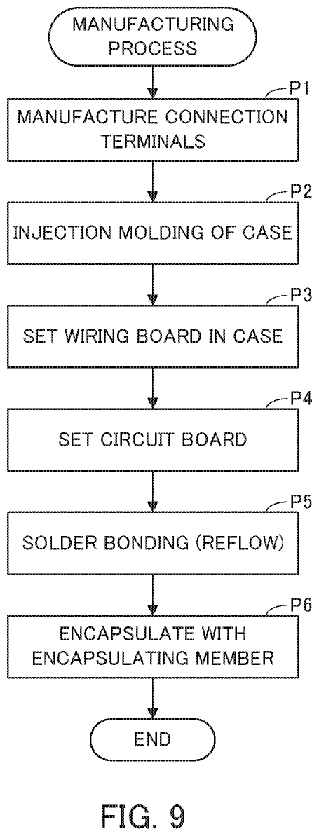

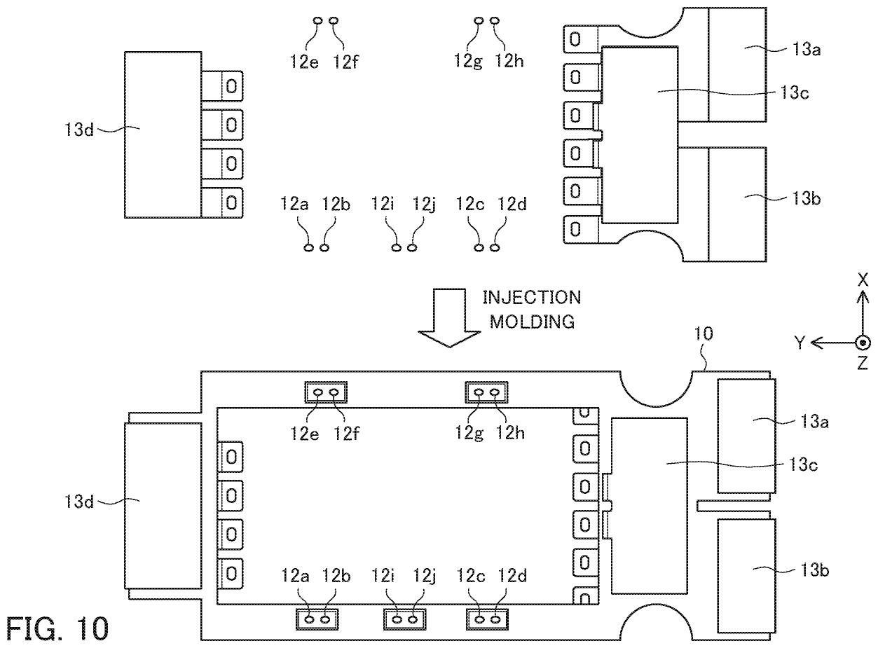

Next, a manufacturing process of the semiconductor device 1 will be described. FIG. 9 is a flowchart depicting a manufacturing process of the semiconductor device.

[Step P1] The first external connection terminals 12a to 12j and the second external connection terminals 13a to 13d are manufactured.

[Step P2] The case 10 is manufactured by injection molding of resin material. In this step, the case 10, which includes the first external connection terminals 12a to 12j and the second external connection terminals 13a to 13d and in which the housing member 10a and the terminal holding members 10b and 10c are integrally molded using a resin material, is manufactured. Note that step P2 will be described in detail later with reference to FIG. 10.

[Step P3] The wiring board 20 is set in the case 10. In this step, the wiring board 20 is attached to the rear surface (the surface on the housing region 11e side) of the upper surface portion 11a of the case 10 in a state where the case 10 and the wiring board 20 have been vertically inverted. In more detail, the wiring board 20 is placed close to the rear surface of the upper surface portion 11a, and the end portions of the first external connection terminals 12a to 12j are inserted into the wiring holes 22a to 22j of the wiring board 20. When the wiring board 20 is pressed against the upper surface portion 11a, the first external connection terminals 12a to 12j are press-fitted into the wiring holes 22a to 22j. Such press-fitting is performed until a predetermined gap is produced between the rear

surface of the upper surface portion 11a and the wiring board 20.

[Step P4] The circuit board 30 is set in the case 10 to which the wiring board 20 has been attached. In this step, the orientation of the case 10 in the vertical direction is changed so that the main surface of the case 10 (the surface from which the second external connection terminals 13a to 13d are exposed) faces upward. Also, on the circuit board 30, solder for bonding to the corresponding wiring pins is applied to the electrodes on the upper surfaces of the semiconductor chips 31a to 31e. After this, the circuit board 30 is placed close to the wiring board 20 from the lower surface side of the upper surface portion 11a to dispose the circuit board 30 at a position where there is a predetermined interval between the circuit board 30 and the wiring board 20.

[Step P 5] Reflowing of the solder is performed. The case 10 in which the wiring board 20 and the circuit board 30 were set in steps P3 and P4 is heated to melt the solder of the electrodes on the upper surfaces of the semiconductor chips 31a to 31e. After the solder has melted, cooling is performed to solidify the solder and thereby bond the electrodes on the upper surfaces of the semiconductor chips 31a to 31e and the corresponding wiring pins via the solder.

[Step P6] The case 10 is set in a cavity of a predetermined molding apparatus. When doing so, the lid member 10d is also disposed in the cavity to produce a state where the lid member 10d covers the second opening 11d of the housing member 10a of the case 10. In this molding apparatus, the molten encapsulating material inside a pod is pressurized using a plunger and is fed from the pod to runners to inject the encapsulating material from gates into gate openings, described later, of openings (including the first opening 11c) in side portions in the X-axis direction of the housing member 10a.

The encapsulating material injected into the case 10 is cured so that the wiring board 20, the circuit board 30, and the semiconductor chips 31a to 31e are encapsulated by the encapsulating member 40. The semiconductor device 1 depicted in FIGS. 1 and 2 is obtained by such transfer molding of the case 10.

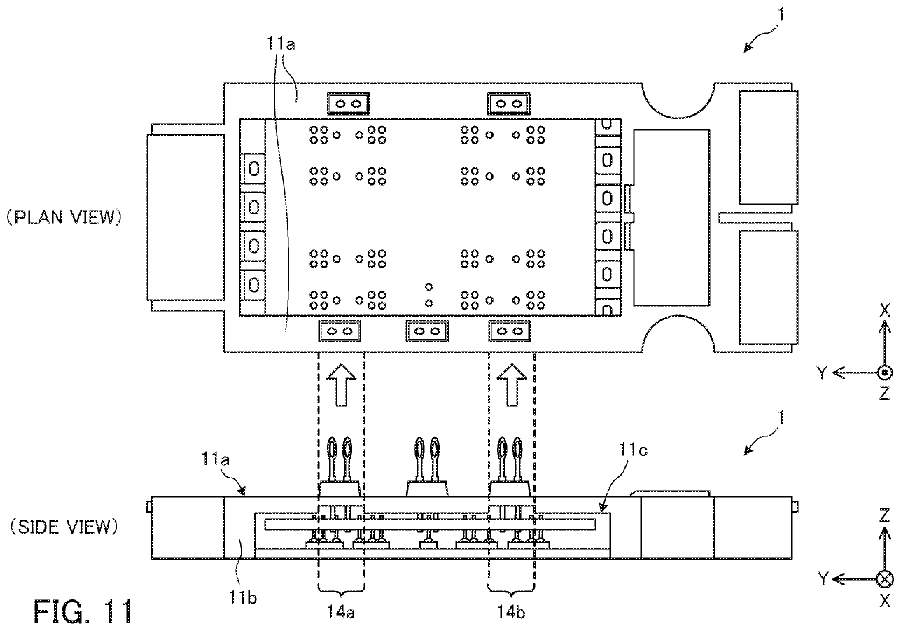

Note that step P6 will be described in detail with reference to FIG. 11.

FIG. 10 depicts a process of integrally molding the case and the external connection terminals.

In step P2 of FIG. 9, the first external connection terminals 12a to 12j, the second external connection terminals 13a to 13d manufactured in step P1 and the case 10 are integrally molded by injection molding. In this step P2, for example, a predetermined die in which the first external connection terminals 12a to 12j and the second external connection terminals 13a to 13d have been set is filled with a resin material. After the filled resin material has cured, the die is removed. By doing so, the case 10 that includes the first external connection terminals 12a to 12j and the second external connection terminals 13a to 13d and in which the housing member 10a and the terminal holding members 10b and 10c are integrally formed is manufactured.

Although the case where there is an opening in the upper surface portion 11a of the case 10 has been described here, the upper surface portion 11a may be covered without including an opening, as described later.

By molding as described above, it is possible to increase the degree of freedom in designing the attachment positions and the attached number of the external connection terminals with respect to the case 10. As one example, as described above, there is an increased degree of freedom in designing the attachment positions and the number of the first external connection terminals 12a to 12j that extend in the vertical direction (the Z-axis direction). In addition, the attachment position accuracy of the first external connection terminals 12a to 12j is also improved.

It is also possible to increase the design freedom for the second external connection terminals 13a to 13d that include the flat plate portions 13a1 to 13d1, respectively. For example, the second external connection terminals 13a and 13b and the second external connection terminal 13c are separated from each other so as not to be electrically connected but are disposed so as to partially overlap each other in the vertical direction (Z-axis direction). It is possible to easily manufacture the case 10 including the second external connection terminals 13a and 13b and the

second external connection terminal 13c in this positional relationship by injection molding.

FIG. 11 depicts a step of injecting the encapsulating member from gate ports. FIG. 11 is a plan view and a side view of the semiconductor device 1 in a state where the encapsulating member 40 and the lid member 10d have been removed.

As described above, an opening is formed in an X-axis direction side wall of the housing member 10a. As one example, the first opening 11c is formed in the −X direction side wall 11b. In step P6 of FIG. 9, the encapsulating member 40 is injected from this opening to encapsulate the inside of the housing member 10a of the case 10.

As depicted in FIG. 11, as one example in the present embodiment, a partial region of the first opening 11c is enlarged in the upward direction (the +Z direction), and this enlarged region constructs gate ports 14a and 14b for injecting the encapsulating material of the encapsulating member 40 in step P6. In the example in FIG. 11, the encapsulating material of the encapsulating member 40 is injected into the gate ports 14a and 14b in the +X direction.

The encapsulating by the encapsulating member 40 in the step P6 may be performed in a state where the non-encapsulated semiconductor device 1 depicted in FIG. 11 has been inverted.

As described earlier, the case 10 is manufactured by injection molding. This improves the degree of freedom in designing the positions and shapes of the openings and gate ports in the X-axis direction side wall of the housing member 10a.

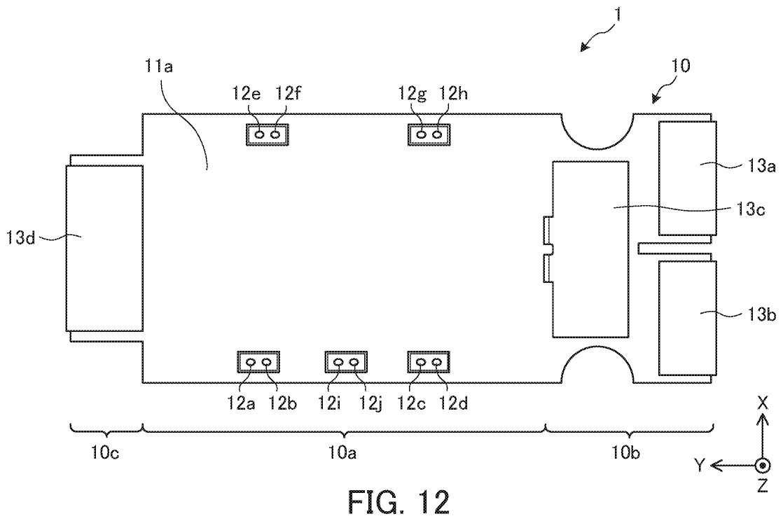

Next, a modification in which the upper structure of the housing member 10a is modified will be described. FIG. 12 is a plan view depicting a modification of the semiconductor device.

In the example in FIG. 12, the second opening 11d is not formed in the upper surface portion 11a of the housing member 10a, and the entire upper surface of the housing region 11e is covered by the upper surface portion 11a which is rectangular in plan view. The housing member 10a of this form is integrally molded with the terminal holding members 10b and 10c by injection molding of resin.

For a case where the second opening 11d is formed in the upper surface portion 11a as depicted in FIG. 1 for example, when the wiring board 20 has been attached to the case 10 in step P3 of FIG. 9, it is possible to visually check the inside of the housing region 11e from the second opening 11d and check the quality of the wiring board 20. 113 When the second opening 11d is formed in this way, the inside of the housing region 11e may be encapsulated with the encapsulating member 40 without covering the second opening 11d with the lid member 10d. When doing so, as one example, the encapsulating member 40 fills the inside of the second opening 11d beyond the lower surface of the upper surface portion 11a and a region up to the upper surface of the upper surface portion 11a in the second opening 11d is encapsulated by the encapsulating member 40. However, in this case, the encapsulating material is likely to leak from the second opening 11d during transfer molding, and removal of the encapsulating material (that is, burrs) that has leaked from the second opening 11d after the encapsulating material is cured may be needed. In the example of FIG. 1, to prevent this situation, the second opening 11d is covered by the lid member 10d before the transfer molding is performed in step P6 of FIG. 9. Alternatively, as described above, when transfer molding is performed in a state where the non-encapsulated semiconductor device 1 depicted in FIG. 11 has been vertically inverted, although the second opening 11d of the housing member 10a will be closed by the lower die, it will be difficult to completely prevent leakage of the encapsulating material.

On the other hand, in a case where it is unnecessary to check the quality of the wiring board 20 attached to the case 10 or in a case where priority is given to the manufacturing efficiency of the semiconductor device 1, it is possible to prevent leakage of the encapsulating material during transfer molding by molding the case 10 with a shape where the upper surface portion 11a is covered from the start as depicted in FIG. 12.

By integrally molding the first external connection terminals 12a to 12j, the second external connection terminals 13a to 13d, and the case 10 by injection molding, as described above, it is possible to easily form both the case 10 with a shape where the second opening 11d is provided in the upper surface portion 11a of the housing member 10a and the case 10 with a shape in which the second opening 11d is not provided by using dies corresponding to the respective shapes.

According to the technology disclosed here, it is possible to increase the strength of the load applied to external connection terminals.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a circuit board;
a case which includes a housing member with a rectangular outer shape in a plan view of the semiconductor device and houses the circuit board, the housing member including an upper surface portion having a lower surface thereof facing an upper surface of the housed circuit board with a gap therebetween, the upper surface portion including a first edge portion at an edge thereof in the plan view;
a first external connection terminal that is held by the first edge portion and protrudes from the first edge portion in a direction that is perpendicular to an upper surface of the first edge portion; and
an encapsulating member that encapsulates the gap between the upper surface of the circuit board and the lower surface of the upper surface portion.

2. The semiconductor device according to claim 1, wherein
the case further includes a side wall that is formed below the first edge portion, and
a first opening for injecting the encapsulating member is formed on a lower side of the side wall.

3. The semiconductor device according to claim 1, wherein said first external connection terminal is provided in a plurality, and the plurality of the first external connection terminals are arranged along the first edge portion.

4. The semiconductor device according to claim 1, wherein
the upper surface portion further includes a second edge portion, opposite to the first edge portion, at another edge thereof in the plan view, and
said first external connection terminal is provided in a plurality, and at least one of the plurality of first external connection terminals is disposed on each of the first edge portion and the second edge portion.

5. The semiconductor device according to claim 1, wherein
the case further includes a terminal holding member provided adjacent to the housing member in a direction along the first edge portion, and
the semiconductor device further comprises a second external connection terminal with a flat plate portion that is parallel to an upper surface of the upper surface portion and is held by the terminal holding member.

6. The semiconductor device according to claim 5, wherein the case, the first external connection terminal, and the second external connection terminal are integrally molded in a state where the housing member encapsulates part of the first external connection terminal and the terminal holding member encapsulates part of the second external connection terminal.

7. The semiconductor device according to claim 1, wherein
a second opening is formed at a center of the housing member in the plan view and the housing member is shaped as a frame that defines the second opening, and
the case further includes a lid member that covers the second opening.

8. The semiconductor device according to claim 1, wherein the housing member has a shape in which an inner region is covered with respect to an outside of the first edge portion in the plan view.

9. The semiconductor device according to claim 1, further comprising a wiring board that is disposed between the upper surface of the circuit board and the lower surface of the upper surface portion, with a gap from each of the upper surface of the circuit board and the lower surface of the upper surface portion, the wiring board having a wiring hole that passes through a region below the first edge portion, wherein
a lower end of the first external connection terminal protrudes from a lower surface of the first edge portion, is inserted into the wiring hole, and is electrically connected to the wiring board.

10. The semiconductor device according to claim 9, further comprising a semiconductor chip disposed on an upper surface of the circuit board, wherein
the wiring board further includes a wiring pin that protrudes from a lower surface of the wiring board, and
an upper surface of the semiconductor chip and a lower end of the wiring pin are bonded to each other via solder.

11. A method of manufacturing a semiconductor device, comprising:
preparing
a circuit board,
a case, which includes a housing member with a rectangular outer shape in a plan view of the semiconductor device and houses the circuit board, the housing member having an upper surface portion that includes a first edge portion at an edge thereof in the plan view, and
a first external connection terminal held by the first edge portion, and protrudes in a direction that is perpendicular to an upper surface of the first edge portion;
disposing the case and the circuit board so that a lower surface of the upper surface portion faces an upper surface of the circuit board with a gap therebetween; and
encapsulating the gap with an encapsulating member.

12. The method of manufacturing a semiconductor device according to claim 11, wherein the preparing of the case includes integrally molding the housing member of the case and the first external connection terminal by encapsulating part of the first external connection terminal in a material forming the case.

13. The method of manufacturing a semiconductor device according to claim 11, wherein
the case further includes a side wall that is formed below the first edge portion, and a first opening is formed at a lower side of the side wall; and
the encapsulating member is injected from the first opening into the gap between the upper surface of the circuit board and the lower surface of the upper surface portion.

14. The method of manufacturing a semiconductor device according to claim 11, wherein
the case further includes a terminal holding member provided adjacent to the housing member in a direction along the first edge portion, and the semiconductor device further includes a second external connection terminal with a flat plate portion that is parallel to an upper surface of the upper surface portion and is held by the terminal holding member, and
the preparing of the case includes integrally molding the housing member and the terminal holding member of the case, the first external connection terminal, and the second external connection terminal by encapsulating part of the first external connection terminal and part of the second external connection terminal in a material forming the case.

15. The method of manufacturing a semiconductor device according to claim 11, wherein
a lower end of the first external connection terminal protrudes from a lower surface of the first edge portion,
the preparation step further prepares a wiring board through which a wiring hole passes, and
the disposing includes:
placing the wiring board closer to the first edge portion with the upper surface of the wiring board facing the lower surface of the first edge portion, and press-fitting a lower end of the first external connection terminal into the wiring hole to electrically connect the wiring hole and the first external connection terminal in a state where a first gap is provided between the upper surface of the wiring board and the lower surface of the first edge portion; and
placing the circuit board below the wiring board so that a lower surface of the wiring board facing the upper surface of the circuit board with a second gap therebetween.

16. The method of manufacturing a semiconductor device according to claim 15, wherein
a semiconductor chip is disposed on the upper surface of the circuit board,
the wiring board further includes a wiring pin that protrudes from the lower surface of the wiring board, and
the method further comprises, after the circuit board has been disposed below the wiring board, bonding an upper surface of the semiconductor chip and a lower end of the wiring pin via solder in a second gap between the upper surface of the circuit board and the lower surface of the wiring board.
